(19) United States
(12) Patent Application Publication
(10) Pub. No.: US 2021/0305019 A1
(43) Pub. Date: Sep. 30, 2021

(54) DOUBLE-SIDED DEPOSITION APPARATUS AND METHOD

(71) Applicant: Piotech Inc., Shenyang (CN)

(72) Inventors: Brian Lu, Shenyang (CN); Saiqian Zhang, Shenyang (CN); Zhongwu Liu, Shenyang (CN)

(21) Appl. No.: 17/205,762

(22) Filed: Mar. 18, 2021

(30) Foreign Application Priority Data
Mar. 25, 2020 (CN) 202010221138.X

(51) Int. Cl. H01J 37/32; C23C 16/458; C23C 16/455; C23C 16/509

(52) U.S. Cl. CPC H01J 37/32403; H01J 37/32568; H01J 37/3244; H01J 37/32715; H01J 2237/20235; C23C 16/4586; C23C 16/45565; C23C 16/509; H01J 2237/3321; H01J 37/32082

(57) ABSTRACT

This application relates to a double-sided deposition apparatus and method. The double-sided deposition apparatus includes: a chamber; an upper electrode disposed in the chamber and including a first showerhead, wherein the first showerhead is configured to provide a first reaction gas to an upper surface of a wafer, to form a first plasma region between the upper electrode and the upper surface of the wafer; and a lower electrode disposed in the chamber and including a second showerhead, wherein the second showerhead is configured to provide a second reaction gas to a lower surface of the wafer, to form a second plasma region between the lower electrode and the lower surface of the wafer, and wherein a period during which the first showerhead provides the first reaction gas at least partially overlaps a period during which the second showerhead provides the second reaction gas.

### BACKGROUND OF THE INVENTION

### 1. Field of the Invention

This application generally relates to double-sided deposition technologies, and more specifically, to plasma enhanced chemical vapor deposition (PECVD) apparatuses and methods capable of double-sided simultaneous deposition.

### 2. Description of the Related Art

Chemical vapor deposition (CVD) is a process technology that causes a reaction substance(s) to produce a chemical reaction(s) under gaseous conditions to generate a solid substance(s) deposited on a surface of a heated solid substrate, resulting in the production of solid material(s), and is generally used for producing thin films (such as films made of polysilicon, amorphous silicon, or silicon oxide). To enable chemical reactions to be performed at relatively low temperature, a plasma processing technology may be introduced into the CVD process, to promote the reactions by using the activity of plasmas. This is a plasma enhanced chemical vapor deposition (PECVD) technology. The PECVD technology ionizes gas including composition(s) of a thin film by microwave or radio frequency, etc., to form plasmas locally. The plasmas have very strong chemical activity and are prone to react, so that a desired thin film is deposited on a wafer.

For novel semiconductor devices such as a heterojunction (HIT) solar cell, it is needed to deposit several layers of thin films on both a front side and a back side of the wafer. In addition, in applications of manufacturing some microelectronic devices, for example, a 3D NAND flash memory, a relatively thick film layer deposited on the front side of the wafer may introduce relatively more stress in the wafer, resulting in wafer warpage. Therefore, in such applications, deposition is also required on the back side of the wafer to balance the stress and prevent the wafer warpage.

For such applications that require deposition on both the front side and the back side of the wafer, generally, deposition is first performed on one side (for example, the front side) of the wafer, and deposition is then performed on the other side (for example, the back side) of the wafer. Such deposition manner has cumbersome operations and take a long time, resulting in low production capacities, high device costs, and high production costs. Moreover, during deposition on the back side, the wafer may be further needed to be turned over. Additional problems such as additional carrying, potential particle exposure, and reduced process yield, may be introduced in the turnover process.

Therefore, how to improve the production capacities and reduce the processing costs of a single wafer is an important issue.

### SUMMARY OF THE INVENTION

In an aspect, this application provides a double-sided deposition apparatus, including: a chamber; an upper electrode disposed in the chamber and including a first showerhead, wherein the first showerhead is configured to provide a first reaction gas to an upper surface of a wafer, to form a first plasma region between the upper electrode and the upper surface of the wafer; and a lower electrode disposed in the chamber and including a second showerhead, wherein the second showerhead is configured to provide a second reaction gas to a lower surface of the wafer, to form a second plasma region between the lower electrode and the lower surface of the wafer, and wherein a period during which the first showerhead provides the first reaction gas at least partially overlaps a period during which the second showerhead provides the second reaction gas.

In some embodiments, the double-sided deposition apparatus further includes: a wafer support structure disposed between the upper electrode and the lower electrode and configured to support the wafer; and a radio frequency power supply coupled to at least one of the upper electrode and the lower electrode, and configured to provide radio frequency power, to form, between the upper electrode and the upper surface of the wafer, the first plasma region for depositing a first thin film on the upper surface of the wafer and form, between the lower electrode and the lower surface of the wafer, the second plasma region for depositing a second thin film on the lower surface of the wafer, wherein the first thin film is generated from the first reaction gas, and the second thin film is generated from the second reaction gas.

In some embodiments, the wafer support structure is made of a non-conductive material. According to an embodiment of this application, one of the upper electrode and the lower electrode is coupled to the radio frequency power supply, and the other of the upper electrode and the lower electrode is grounded.

In some embodiments, the wafer support structure is made of a conductive material. According to an embodiment of this application, the radio frequency power supply includes a first radio frequency power supply and a second radio frequency power supply, the upper electrode is coupled to the first radio frequency power supply, the lower electrode is coupled to the second radio frequency power supply, and the wafer support structure is grounded. The first radio frequency power supply and the second radio frequency power supply have the same frequency and are phase-difference-locked. In some embodiments, the first radio frequency power supply and the second radio frequency power supply are two parts formed by the same radio frequency power supply through a power divider. A power ratio of the two parts may be 1:1, or is adjustable.

In some embodiments, the wafer support structure is in the shape of a circular ring, a rectangular ring, or a ring having a circular outer periphery and a rectangular inner periphery.

In some embodiments, a side wall of the chamber includes a gas outlet hole for extracting a gas from the chamber.

In some embodiments, at least one of the upper electrode and the lower electrode includes a heater.

In some embodiments, the wafer support structure includes a movement structure, so that the wafer support structure is able to move upward or downward.

In another aspect, this application provides a method for processing a wafer in the double-sided deposition apparatus according to the embodiments of this application. The method includes: providing the wafer to a wafer support structure between the upper electrode and the lower electrode; providing the first reaction gas by using the first showerhead; providing the second reaction gas by using the second showerhead; and providing radio frequency power of a radio frequency power supply to at least one of the upper electrode and the lower electrode, to deposit a first thin film on the upper surface of the wafer and deposit a second thin film on the lower surface of the wafer.

In some embodiments, both the wafer and the wafer support structure are made of non-conductive materials. Providing the radio frequency power to the at least one of the upper electrode and the lower electrode may include: providing the radio frequency power to one of the upper electrode and the lower electrode, and grounding the other of the upper electrode and the lower electrode.

In some embodiments, both the wafer and the wafer support structure are made of conductive materials. The radio frequency power supply may include a first radio frequency power supply and a second radio frequency power supply, and providing the radio frequency power to the at least one of the upper electrode and the lower electrode may include: applying the first radio frequency power supply to the upper electrode, applying the second radio frequency power supply to the lower electrode, and grounding the wafer support structure. The first radio frequency power supply and the second radio frequency power supply have the same frequency and are phase-difference-locked. In some embodiments, the first radio frequency power supply and the second radio frequency power supply are two parts formed by the same radio frequency power supply through a power divider. A power ratio of the two parts may be 1:1. In some other embodiments, the method further includes: adjusting the power ratio of the two parts.

In some embodiments, the method further includes: extracting a gas from the chamber through a gas outlet hole on a side wall of the chamber.

In some embodiments, the method further includes: heating at least one of the upper electrode and the lower electrode.

In some embodiments, the method further includes: adjusting a position, between the upper electrode and the lower electrode, of the wafer support structure upward or downward.

In some embodiments, the method further includes: adjusting a flow rate of at least one of the first reaction gas and the second reaction gas.

Details of one or more examples of this application are described in the following accompanying drawing and descriptions. Other features, targets, and advantages are obvious according to the descriptions, the accompanying drawing, and the claims.

### BRIEF DESCRIPTION OF THE DRAWINGS

The present disclosure in this specification mentions and includes the following figures:

FIG. 1 illustrates a schematic structural diagram of a double-sided deposition apparatus according to some embodiments of this application;

FIG. 2 illustrates schematic diagrams of cross sections of wafer support structures according to some embodiments of this application;

FIG. 3 illustrates a schematic structural diagram of a double-sided deposition apparatus according to some embodiments of this application;

FIG. 4 illustrates a schematic structural diagram of a double-sided deposition apparatus according to some other embodiments of this application;

FIG. 5 illustrates a schematic diagram of supplying power by dual radio frequency power supplies according to some embodiments of this application;

FIG. 6 illustrates a schematic diagram of supplying power by dual radio frequency power supplies according to some other embodiments of this application; and

FIG. 7 illustrates a flowchart of a method for processing a wafer in a double-sided deposition apparatus according to some embodiments of this application.

As customary, various features described in the figures may not be drawn to scale. Therefore, the sizes of the various features may be increased or reduced arbitrarily for the purpose of clear descriptions.

In addition, for clarity, implementation solutions illustrated in the figures may be simplified. Therefore, the figures may not illustrate all components of a specified device or apparatus. Finally, this specification and the figures may use the same reference numerals to represent the same features.

### PREFERRED EMBODIMENT OF THE PRESENT INVENTION

The following more completely describes the present invention with reference to the figures, and exemplary specific embodiments are displayed by using examples. However, the claimed subject may be specifically implemented in many different forms. Therefore, the construction of the claimed subject that is covered or applied is not limited to any exemplary specific embodiments disclosed in this specification. The exemplary specific embodiments are merely examples. Similarly, the present invention aims to provide a reasonable broad scope for the claimed subject that is applied or covered. In addition, for example, the claimed subject may be specifically implemented as a method, an apparatus, or a system. Therefore, the specific embodiments may use a form of, for example, hardware, software, firmware, or a combination (known not to be software) thereof.

The phrase “in one embodiment” or “according to an embodiment” used in this specification does not necessarily refer to the same specific embodiment, and the phrase “in (some) other embodiments” or “according to (some) other embodiments” used in this specification does not necessarily refer to different specific embodiments. An objective is that, for example, the claimed subject includes a combination of all or a part of the exemplary specific embodiments. The meaning of “upper” and “lower” in this specification is not intended to be limited to a relationship directly presented in the figures, and should include descriptions having an explicit correspondence, for example, “left” and “right,” or the opposite of “upper” and “lower.” The term “wafer” in this specification should be understood to be used interchangeably with the terms such as a “base plate” and a “substrate.” The term “coupled” in this specification should be understood to cover the terms “directly connected” and “connected through one or more intermediate components.”

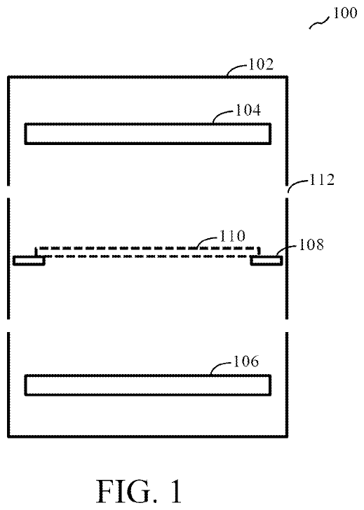

FIG. 1 illustrates a schematic structural diagram of a double-sided deposition apparatus 100 for processing a wafer 110 according to some embodiments of this application. The apparatus 100 includes a chamber 102, an upper electrode 104, a lower electrode 106, and a wafer support structure 108.

The upper electrode 104 is disposed in the chamber 102, and faces an upper surface of the wafer 110. The upper electrode 104 may be provided with or include a first showerhead structure (not shown), to provide a first reaction gas to the chamber 102, and the first reaction gas is used for depositing a first thin film on the upper surface of the wafer 110. The first showerhead structure may include a plurality of shower holes that is substantially uniformly distributed, to achieve uniform gas distribution. In some embodiments, different arrangement forms of the shower holes may be used.

The lower electrode 106 is disposed in the chamber 102, and faces a lower surface of the wafer 110. The lower electrode 106 may be provided with or include a second showerhead structure (not shown), to provide a second reaction gas to the chamber 102, and the second reaction gas is used for depositing a second thin film on the lower surface of the wafer 110. The second showerhead structure may include a plurality of shower holes that is substantially uniformly distributed, to achieve uniform gas distribution. In some embodiments, different arrangement forms of the shower holes may be used.

Although it is not shown in FIG. 1, a person skilled in the art should understand that, the apparatus 100 may further include a top gas inlet pipe(s) and a bottom gas inlet pipe(s), which convey the first reaction gas and the second reaction gas to the upper electrode 104 and the lower electrode 106 respectively. The top gas inlet pipe(s) and the bottom gas inlet pipe(s) may admit a gas simultaneously. In some embodiments, a gas conveying speed of the top gas inlet pipe(s) and/or the bottom gas inlet pipe(s) may be separately controlled to adjust a flow rate of the first reaction gas and/or the second reaction gas.

According to some embodiments of this application, at least one of the upper electrode 104 and the lower electrode 106 may include a heater (not shown), to raise temperature of the wafer surfaces and the reaction gas, and further promote the reaction. For example, the heater may be buried in the upper electrode 104, or the heater may be buried in the lower electrode 106, or the heater may be buried in both the upper electrode 104 and the lower electrode 106. In the process of processing the wafer 110, the at least one of the upper electrode 104 and the lower electrode 106 may be heated as required, to adjust a film forming speed of the upper surface and/or the lower surface of the wafer 110.

A side wall of the chamber 102 may be implemented as a baffle plate or a similar structure. A plurality of gas outlet holes 112 may be provided on the side wall, and is configured to extract a gas from a side, to achieve uniform gas distribution in the chamber 102. Therefore, the gas outlet holes 112 are also referred to as uniform-gas holes. For purposes of illustration, FIG. 1 shows four gas outlet holes. A person skilled in the art should understand that, the side wall of the chamber 102 may be provided with more or fewer gas outlet holes, and positions of the gas outlet holes may be different from those shown in FIG. 1.

The wafer support structure 108 may be disposed between the upper electrode 104 and the lower electrode 106, and is configured to support the wafer 110. Although it is not shown in FIG. 1, a person skilled in the art should understand that, a connection structure(s) may be disposed between the wafer support structure 108 and a top, the side wall, or a bottom of the chamber 102, so that the wafer support structure 108 can be located at an appropriate height in the chamber 102. In some embodiments, the wafer support structure 108 may further include a movement structure, so that the wafer support structure 108 is able to move upward or downward. To allow deposition on the lower surface of the wafer 110, the wafer support structure 108 surrounds the wafer 110 in an annular shape, supports the wafer 110 at an edge thereof, and exposes a part of the lower surface of the wafer 110 on which a thin film needs to be deposited.

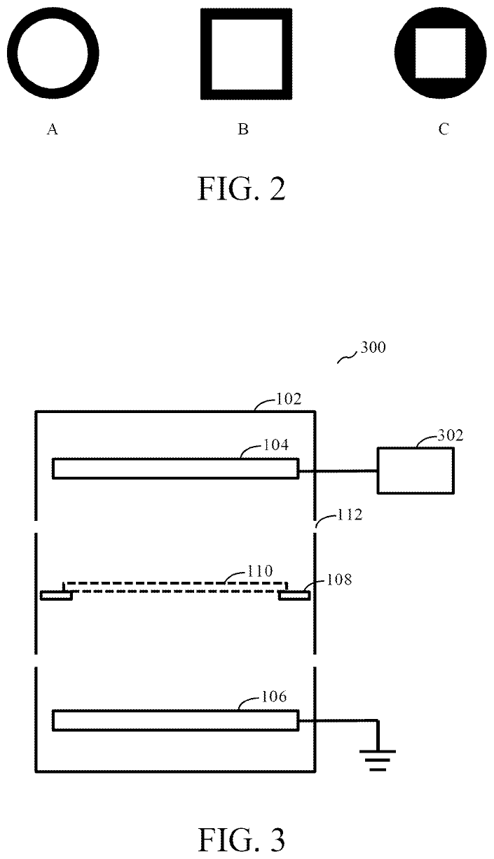

For different wafer shapes and chamber structures, the wafer support structure 108 may be designed with different cross section shapes. FIG. 2 illustrates schematic diagrams of cross sections of several wafer support structures according to some embodiments of this application. For example, for a circular wafer and a circular chamber, wafer support structures in the shape of a circular ring of class A may be used. For a rectangular wafer and a rectangular chamber, wafer support structures in the shape of a rectangular ring of class B may be used. For a rectangular wafer and a circular chamber, wafer support structures in the shape of a ring having a circular outer periphery and a rectangular inner periphery of class C may be used. It should be understood that, the cross sections of the several wafer support structures provided in FIG. 2 are merely provided for purposes of illustration, and should not be regarded as a limitation to the present invention.

The apparatus 100 shown in FIG. 1 may further include a radio frequency power supply (not shown). The radio frequency power supply is coupled to at least one of the upper electrode 104 and the lower electrode 106, and is configured to provide radio frequency power, to form, between the upper electrode 104 and the upper surface of the wafer 110, a first plasma region for depositing a first thin film on the upper surface of the wafer 110 and simultaneously form, between the lower electrode 106 and the lower surface of the wafer 110, a second plasma region for depositing a second thin film on the lower surface of the wafer 106. The term “simultaneously” herein does not require that a period of time during which the first plasma region is formed completely overlaps a period of time during which the second plasma region is formed. As long as the two periods of time are at least partially overlapped, this is referred to as “simultaneously.”

Different from an apparatus that performs deposition on one surface of the wafer each time, in the apparatus 100, the wafer 110 and the wafer support structure 108 divide the chamber 102 is divided into an upper space and a lower space. The two spaces need to meet process conditions, for example, a distance, temperature, uniformity of gas distribution between a wafer surface and a corresponding showerhead, of depositing the first thin film and the second thin film respectively. After the radio frequency power is applied, electric fields similar to that formed during a single-sided deposition are formed in both the upper space and the lower space, and the electric field in each space is similar in time and spatial distributions to that formed during a single-sided deposition. Materials and electric potentials of the wafer 110 and the wafer support structure 108 also may affect the distribution of the electric fields, and further affect the distribution of plasma generated by ionization and the quality of deposited thin films. Therefore, according to the embodiments of this application, for the wafers with different materials, the wafer support structures with different materials may be used, and different manners of applying radio frequency power may be used, to obtain a thick film with a good uniformity and a controllable film thickness on both sides.

FIG. 3 illustrates a schematic structural diagram of a double-sided deposition apparatus 300 according to some embodiments of this application. The apparatus 300 may be an example of the apparatus 100 in FIG. 1. The same reference numerals used in FIG. 3 represent the same components as those in FIG. 1, for example, the chamber 102, the upper electrode 104, the lower electrode 106, and the wafer support structure 108.

In the embodiment shown in FIG. 3, the wafer 110 is made of a non-conductive material (such as glass), and the wafer support structure 108 may be also made of a non-conductive material. The upper electrode 104 is coupled to the radio frequency power supply 302, and the lower electrode 106 is grounded. Although FIG. 3 shows that the upper electrode 104 is directly connected to the radio frequency power supply 302, a person skilled in the art should understand that, the radio frequency power supply 302 may be connected to the upper electrode through a corresponding matching circuit, to obtain better radio frequency efficiency. In other embodiments, alternatively, the lower electrode 106 may be coupled to the radio frequency power supply, and the upper electrode 104 is grounded. The wafer 110 and the wafer support structure 108 are neither coupled to the radio frequency power supply nor grounded. That is, both the wafer 110 and the wafer support structure 108 are at floating potentials. Applying the radio frequency power in such a configuration manner may cause electric potentials of the wafer 110 and the wafer support structure 108 to be close, so that they may form an electrode as a whole, and better film thickness uniformity is achieved.

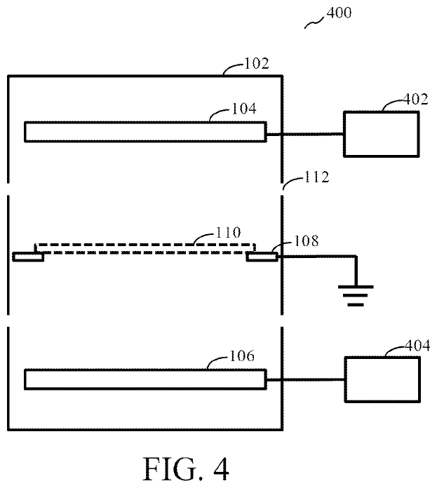

FIG. 4 illustrates a schematic structural diagram of a double-sided deposition apparatus 400 according to some other embodiments of this application. The apparatus 400 may be an example of the apparatus 100 in FIG. 1. The same reference numerals used in FIG. 4 represent the same components as those in FIG. 1, for example, the chamber 102, the upper electrode 104, the lower electrode 106, and the wafer support structure 108.

In the embodiment shown in FIG. 4, the wafer 110 is made of a conductive material, and the wafer support structure 108 may be also made of a conductive material (such as metal). The upper electrode 104 is coupled to a first radio frequency power supply 402, the lower electrode 106 is coupled to a second radio frequency power supply 404, and the wafer support structure 108 is grounded. A conductive contact exists between the wafer 110 and the wafer support structure 108. Therefore, the wafer 110 is also actually at a ground potential. That is, the wafer 110 and the wafer support structure 108 have the same potential. Apply the radio frequency power in such a configuration manner may also achieve better film thickness uniformity. In addition, because the first plasma region and the second plasma region are separated by the grounded wafer 110 and wafer support structure 108, and different radio frequency power values may be applied to the upper electrode 104 and the lower electrode 106 respectively, the process conditions on the two sides of the wafer 110 can be adjusted relatively independently. Although FIG. 4 shows that the upper electrode 104 and the lower electrode 106 are directly connected to the first radio frequency power supply 402 and the second radio frequency power supply 404 respectively, a person skilled in the art should understand that, the first radio frequency power supply 402 and the second radio frequency power supply 404 may be connected to the upper electrode 104 and the lower electrode 106 respectively through corresponding matching circuits, to obtain better radio frequency efficiency.

In some embodiments of this application, the first radio frequency power supply 402 and the second radio frequency power supply 404 may be two different radio frequency power supplies. Two electric fields are formed in the chamber 102 by applying the two radio frequency power supplies. To prevent plasma generated by ionization from being unstable due to beat phenomenon occurring in a region where the two electric fields overlap, the first radio frequency power supply 402 and the second radio frequency power supply 404 should have the same frequency and are phase-difference-locked.

FIG. 5 illustrates a schematic diagram of supplying power by dual radio frequency power supplies according to some embodiments of this application, which is applicable to the apparatus 100 shown in FIG. 1 or the apparatus 400 shown in FIG. 4. For clarity, FIG. 5 merely shows an upper electrode 104 and a lower electrode 106 in a chamber 102, and does not show other components in the chamber 102. As shown in FIG. 5, the upper electrode 104 is coupled to a first radio frequency power supply 502, the lower electrode 106 is coupled to a second radio frequency power supply 504, and the first radio frequency power supply 502 and the second radio frequency power supply 504 may be examples of the first radio frequency power supply 402 and the second radio frequency power supply 404 in FIG. 4. Although FIG. 5 shows that the upper electrode 104 and the lower electrode 106 are directly connected to the first radio frequency power supply 502 and the second radio frequency power supply 504 respectively, a person skilled in the art should understand that, the first radio frequency power supply 502 and the second radio frequency power supply 504 may be connected to the upper electrode 104 and the lower electrode 106 respectively through corresponding matching circuits. The first radio frequency power supply 502 and the second radio frequency power supply 504 have the same frequency, and have a fixed phase difference by using a synchronization circuit 506. A person skilled in the art knows various manners for implementing the synchronization circuit. In some embodiments, a common exciter (CEX) technology may be used to implement phase-difference-lock. Such technology is known to a person skilled in the art. Therefore, details are not described herein.

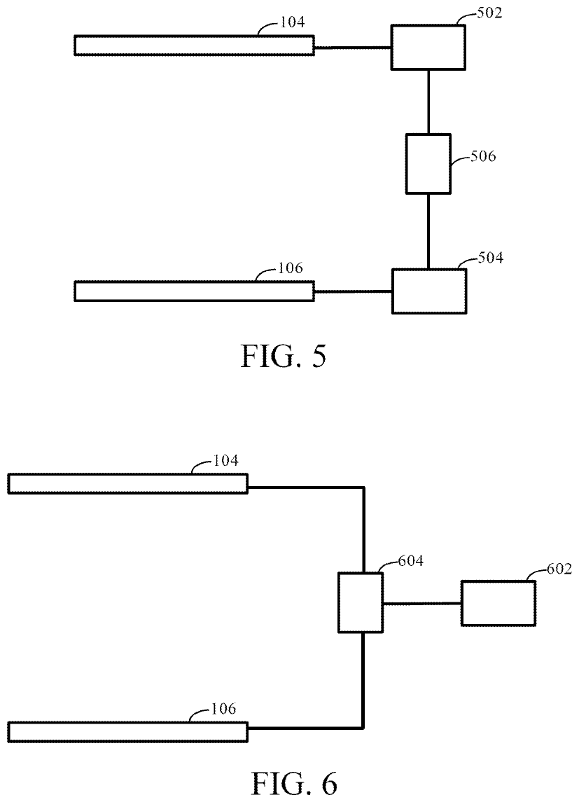

In some other embodiments of this application, the first radio frequency power supply 402 and the second radio frequency power supply 404 may be two parts formed by the same radio frequency power supply through a power divider. FIG. 6 illustrates a schematic diagram of supplying power by dual radio frequency power supplies according to such embodiments, which is applicable to the apparatus 100 shown in FIG. 1 or the apparatus 400 shown in FIG. 4. For clarity, FIG. 6 merely shows an upper electrode 104 and a lower electrode 106 in a chamber 102, and does not show other components in the chamber 102. As shown in FIG. 6, an output of the radio frequency power supply 602 is coupled to the power divider 604. Although FIG. 6 shows that the radio frequency power supply 602 is directly connected to the power divider 604, a person skilled in the art should understand that, the radio frequency power supply 602 may be connected to the power divider 604 through a corresponding matching circuit. The power divider 604 divides the radio frequency power outputted by the radio frequency power supply 602 into two parts according to a specified ratio. A first part (may correspond to the first radio frequency power supply 402 in FIG. 4) is supplied to the upper electrode 104, and a second part (may correspond to the second radio frequency power supply 404 in FIG. 4) is supplied to the lower electrode 106. In some embodiments, the power divider 604 evenly allocates the radio frequency power outputted by the radio frequency power supply 602 to the upper electrode 104 and the lower electrode 106. That is, the power ratio of the two parts is fixed to 1:1. In some other embodiments, the power allocation ratio of the power divider 604 is adjustable. For example, the power ratio of the two parts may be adjusted within a range of 0.9 to 1.1.

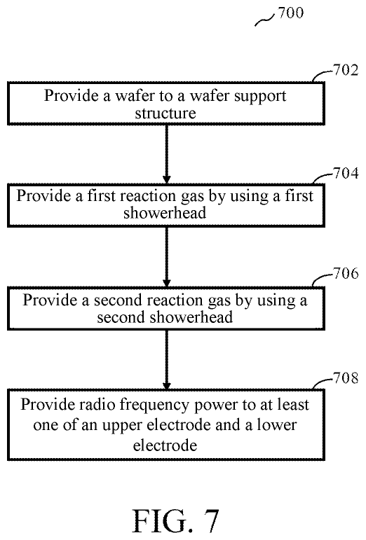

FIG. 7 illustrates a flowchart of a method 700 for processing a wafer in a double-sided deposition apparatus according to some embodiments of this application. The method 700 may be performed in the apparatus 100, the apparatus 300, the apparatus 400, or an apparatus or device having a similar structure or function.

As shown in FIG. 7, in step 702 in the method 700, a to-be-processed wafer (for example, the wafer 110 in FIG. 1, FIG. 3, or FIG. 4) is provided to the wafer support structure (for example, the wafer support structure 108 in FIG. 1, FIG. 3, or FIG. 4). The to-be-processed wafer may be a wafer that needs thin films to be deposited on both a front side and a back side thereof. Then, in step 704, a first reaction gas is provided by using a first showerhead (for example, the showerhead disposed in the upper electrode 104 in FIG. 1, FIG. 3, or FIG. 4). In step 706, a second reaction gas is provided by using a second showerhead (for example, the showerhead disposed in the lower electrode 106 in FIG. 1, FIG. 3, or FIG. 4). Although FIG. 7 shows that step 704 and step 706 are performed sequentially, it should be understood that reversing the execution sequence of the two steps or performing the two steps simultaneously also fall within the scope of the present invention. In addition, step 704 and step 706 can be understood as starting to provide the reaction gas, and the reaction gas should be continuously supplied in the deposition process until the deposition is completed. For example, the first reaction gas is provided within a first duration, and the second reaction gas is provided within a second duration. To deposit on the both sides simultaneously, the first duration and the second duration should be at least partially overlapped.

In step 708, the radio frequency power is provided to at least one of the upper electrode (for example, the upper electrode 104 in FIG. 1, FIG. 3, or FIG. 4) and the lower electrode (for example, the lower electrode 106 in FIG. 1, FIG. 3, or FIG. 4), to deposit a first thin film on an upper surface of the wafer and simultaneously deposit a second thin film on a lower surface of the wafer. The first thin film is generated by the first reaction gas, and the second thin film is generated by the second reaction gas. Similarly, the execution sequence of step 708, step 704, and step 706 may be changed arbitrarily, or they may be performed simultaneously. The radio frequency power should be continuously provided in the deposition process until the deposition is completed.

In some embodiments of this application, the method 700 is applicable to the apparatus 300 as shown in FIG. 3 for processing a wafer made of a non-conductive material. In the embodiments, step 708 may include: providing the radio frequency power (for example, an output power of the radio frequency power supply 302 in FIG. 3) to one (for example, the upper electrode 104 in FIG. 3) of the upper electrode and the lower electrode, and grounding the other (for example, the lower electrode 106 in FIG. 3) of the upper electrode and the lower electrode.

In some other embodiments of this application, the method 700 is applicable to the apparatus 400 as shown in FIG. 4 for processing a wafer made of a conductive material. In the embodiments, step 708 may include: applying the first radio frequency power supply (for example, the first radio frequency power supply 402 in FIG. 4, the first radio frequency power supply 502 in FIG. 5, or the first part of radio frequency power outputted by the power divider 604 in FIG. 6) to the upper electrode (for example, the upper electrode 104 in FIG. 4 to FIG. 6), applying the second radio frequency power supply (for example, the second radio frequency power supply 404 in FIG. 4, the second radio frequency power supply 504 in FIG. 5, and the second part of radio frequency power outputted by the power divider 604 in FIG. 6) to the lower electrode (for example, the lower electrode 106 in FIG. 4 to FIG. 6), and grounding the wafer support structure (for example, the wafer support structure 108 in FIG. 4). According to an embodiment of this application, the method 700 may additionally include a step of adjusting a power ratio of the first radio frequency power supply to the second radio frequency power supply, for example, adjusting a power ratio of the two parts by adjusting the power allocation ratio of the power divider 604.

To achieve uniform gas distribution in the chamber, the method 700 may additionally include a step of extracting a gas from the chamber through a gas outlet hole (for example, the gas outlet hole 112 in FIG. 1, FIG. 3, or FIG. 4) on a side wall of the chamber. The method 700 may further additionally include a step of heating at least one of the upper electrode and the lower electrode, to adjust a film forming speed on the upper surface and/or the lower surface of the wafer.

According to some embodiments of this application, the method 700 may further include an additional adjustment step, to adjust the process conditions to some extent in the upper space and the lower space of the chamber divided by the wafer and the wafer support structure. For example, the method 700 may include adjusting a position, between the upper electrode and the lower electrode, of the wafer support structure upward and downward (for example, by using a movement structure of the wafer support structure). For example, the method 700 may further include adjusting a flow rate of at least one of the first reaction gas and the second reaction gas.

This application provides apparatuses and corresponding methods that can implement simultaneous deposition on both sides, thereby achieving effects of improving production capacities and reducing costs. Although the embodiments in this specification are mainly described with reference to a plasma enhanced chemical vapor deposition (PECVD) apparatus and method, the solutions of the present invention may also be applied to other similar apparatuses or methods.

The descriptions in this specification are provided to enable a person skilled in the art to perform or use the present invention. Apparently, a person skilled in the art would easily make various modifications to the present invention, and a generic principle defined in the specification may be applied to other variations without departing from the spirit or scope of the present invention. Therefore, the present invention is not limited to the examples and designs described in this specification, but is given the broadest scope consistent with the principle and novel features disclosed in this specification.

What is claimed is:

1. A double-sided deposition apparatus, comprising:
a chamber;
an upper electrode disposed in the chamber and comprising a first showerhead, wherein the first showerhead is configured to provide a first reaction gas to an upper surface of a wafer, to form a first plasma region between the upper electrode and the upper surface of the wafer; and
a lower electrode disposed in the chamber and comprising a second showerhead, wherein the second showerhead is configured to provide a second reaction gas to a lower surface of the wafer, to form a second plasma region between the lower electrode and the lower surface of the wafer, and
wherein a period during which the first showerhead provides the first reaction gas at least partially overlaps a period during which the second showerhead provides the second reaction gas.

2. The double-sided deposition apparatus according to claim 1, further comprising:
a wafer support structure disposed between the upper electrode and the lower electrode and configured to support the wafer; and
a radio frequency power supply coupled to at least one of the upper electrode and the lower electrode, and configured to provide radio frequency power, to form, between the upper electrode and the upper surface of the wafer, the first plasma region for depositing a first thin film on the upper surface of the wafer and form, between the lower electrode and the lower surface of the wafer, the second plasma region for depositing a second thin film on the lower surface of the wafer, wherein the first thin film is generated from the first reaction gas, and the second thin film is generated from the second reaction gas.

3. The double-sided deposition apparatus according to claim 2, wherein the wafer support structure is made of a non-conductive material.

4. The double-sided deposition apparatus according to claim 3, wherein one of the upper electrode and the lower electrode is coupled to the radio frequency power supply, and the other of the upper electrode and the lower electrode is grounded.

5. The double-sided deposition apparatus according to claim 2, wherein the wafer support structure is made of a conductive material.

6. The double-sided deposition apparatus according to claim 5, wherein the radio frequency power supply comprises a first radio frequency power supply and a second radio frequency power supply, the upper electrode is coupled to the first radio frequency power supply, the lower electrode is coupled to the second radio frequency power supply, and the wafer support structure is grounded.

7. The double-sided deposition apparatus according to claim 6, wherein the first radio frequency power supply and the second radio frequency power supply have the same frequency and are phase-difference-locked.

8. The double-sided deposition apparatus according to claim 6, wherein the first radio frequency power supply and the second radio frequency power supply are two parts formed by the same radio frequency power supply through a power divider.

9. The double-sided deposition apparatus according to claim 8, wherein a power ratio of the two parts is 1:1.

10. The double-sided deposition apparatus according to claim 8, wherein a power ratio of the two parts is adjustable.

11. The double-sided deposition apparatus according to claim 2, wherein the wafer support structure is in the shape of a circular ring, a rectangular ring, or a ring having a circular outer periphery and a rectangular inner periphery.

12. The double-sided deposition apparatus according to claim 1, wherein a side wall of the chamber comprises a gas outlet hole for extracting a gas from the chamber.

13. The double-sided deposition apparatus according to claim 1, wherein at least one of the upper electrode and the lower electrode comprises a heater.

14. The double-sided deposition apparatus according to claim 2, wherein the wafer support structure comprises a movement structure, so that the wafer support structure is able to move upward or downward.

15. A method for processing a wafer in the double-sided deposition apparatus according to claim 1, comprising:
providing the wafer to a wafer support structure between the upper electrode and the lower electrode;
providing the first reaction gas by using the first showerhead;
providing the second reaction gas by using the second showerhead; and
providing radio frequency power of a radio frequency power supply to at least one of the upper electrode and the lower electrode, to deposit a first thin film on the upper surface of the wafer and deposit a second thin film on the lower surface of the wafer.

16. The method according to claim 15, wherein both the wafer and the wafer support structure are made of non-conductive materials.

17. The method according to claim 16, wherein providing the radio frequency power to the at least one of the upper electrode and the lower electrode comprises: providing the radio frequency power to one of the upper electrode and the lower electrode, and grounding the other of the upper electrode and the lower electrode.

18. The method according to claim 15, wherein both the wafer and the wafer support structure are made of conductive materials.

19. The method according to claim 18, wherein the radio frequency power supply comprises a first radio frequency power supply and a second radio frequency power supply, and providing the radio frequency power to the at least one of the upper electrode and the lower electrode comprises: applying the first radio frequency power supply to the upper electrode, applying the second radio frequency power supply to the lower electrode, and grounding the wafer support structure.

20. The method according to claim 19, wherein the first radio frequency power supply and the second radio frequency power supply have the same frequency and are phase-difference-locked.

21. The method according to claim 19, wherein the first radio frequency power supply and the second radio frequency power supply are two parts formed by the same radio frequency power supply through a power divider.

22. The method according to claim 21, wherein a power ratio of the two parts is 1:1.

23. The method according to claim 21, further comprising: adjusting a power ratio of the two parts.

24. The method according to claim 15, wherein the wafer support structure is in the shape of a circular ring, a rectangular ring, or a ring having a circular outer periphery and a rectangular inner periphery.

25. The method according to claim 15, further comprising: extracting a gas from the chamber through a gas outlet hole on a side wall of the chamber.

26. The method according to claim 15, further comprising: heating at least one of the upper electrode and the lower electrode.

27. The method according to claim 15, further comprising: adjusting a position, between the upper electrode and the lower electrode, of the wafer support structure upward or downward.

28. The method according to claim 15, further comprising: adjusting a flow rate of at least one of the first reaction gas and the second reaction gas.
